(19) United States
(12) Patent Application Publication
(10) Pub. No.: US 2002/0141477 A1
(43) Pub. Date: Oct. 3, 2002

(54) Thin film thickness monitoring method and substrate temperature measuring method

(75) Inventors: Hiroshi Akahori, Yokohama-shi (JP); Shuichi Samata, Yokohama-shi (JP)

Correspondence Address: Finnegan, Henderson, Farabow,, Garrett & Dunner, L.L.P., 1300 I Street, N.W., Washington, DC, 20005-3315, US

(73) Assignee: Kabushiki Kaisha Toshiba

(21) Appl. No.: 10/107,361

(22) Filed: Mar. 28, 2002

(30) Foreign Application Priority Data
Mar. 28, 2001 (JP) 2001-094164

(51) Int. Cl. B05D 1/00; F27D 11/00; G01J 5/00; C23C 16/00; A21B 1/00

(52) U.S. Cl. 374/126; 427/9; 219/391

(57) ABSTRACT

A radiant light from a reaction chamber is measured outside the chamber, and a relation between a change of a radiation ratio of the radiant light, and a change of a thickness of a thin film is acquired, when a CVD apparatus is used to form the film on a substrate in the chamber. After acquiring the relation between the change of the radiation ratio and the change of the film thickness, the change of the radiation ratio is measured, when the CVD apparatus is used to form the film. The thickness of the film is estimated from the change of the radiation ratio measured in measuring the change of the radiation ratio from the relation between the change of the radiation ratio and the change of the film thickness acquired in acquiring the relation between the change of the radiation ratio and the change of the film thickness.

### CROSS-REFERENCE TO RELATED APPLICATIONS

This application is based upon and claims the benefit of priority from the prior Japanese Patent Application No. 2001-094164, filed Mar. 28, 2001, the entire contents of which are incorporated herein by reference.

### BACKGROUND OF THE INVENTION

1. Field of the Invention

The present invention relates to a film thickness control of a thin film using a film thickness monitoring method for monitoring a thickness of the thin film on a substrate in a reaction chamber of a CVD apparatus, and a substrate temperature measuring method in a diffusion furnace.

2. Description of the Related Art

A conventional film thickness monitoring method (first related art) for monitoring a thickness of a film formed in a chamber of a CVD apparatus in situ will be described hereinafter.

In the manufacturing of a semiconductor device, a chemical vapor deposition (CVD) apparatus has heretofore been used to form a thin film onto a semiconductor substrate (wafer).

However, the CVD apparatus requires a high-temperature heat process, and there is not a method of monitoring the film thickness in situ during the forming of the thin film by the CVD apparatus. Therefore, it is general to measure the film thickness by the following method under existing circumstances. First, a wafer for a test is simultaneously or continuously subjected to film formation. Subsequently, the wafer for the test is taken out, and the film thickness is separately measured by a film thickness measurement apparatus.

A conventional substrate temperature measuring method in a diffusion furnace (second related art) will next be described.

To measure a substrate temperature in the diffusion furnace (heat treatment furnace) without contaminating the substrate, there is a method of extracting a radiant light from the substrate with a glass fiber, and measuring the temperature with a radiation thermometer. The method can be used to measure the temperature in a sheet type heat treatment furnace.

However, in the first related art, it is impossible to know the film thickness in situ during the film formation, and the film thickness can be confirmed after the film formation. Therefore, with the presence of a trouble that the film having a thickness different from a target thickness is formed because of some factor during the film formation, the film formation in the different film thickness cannot be avoided beforehand.

Moreover, in the second related art, usually, in a batch type diffusion furnace for use in forming a gate oxide film, dummy substrates are disposed above and below a substrate with which a semiconductor device is to be manufactured. Therefore, it is practically impossible to extract the radiant light from the substrate with the glass fiber.

### BRIEF SUMMARY OF THE INVENTION

According to one aspect of the present invention, there is provided a film thickness monitoring method comprising: measuring a radiant light from a reaction chamber outside the reaction chamber, and acquiring a relation between a change of a radiation ratio of the radiant light, and a change of a thickness of a thin film formed on a substrate, when a chemical vapor deposition (CVD) apparatus having the reaction chamber is used to form a thin film on the substrate in the reaction chamber; measuring the change of the radiation ratio of the radiant light, when the CVD apparatus is used to form the thin film on the substrate after acquiring the relation between the change of the radiation ratio and the change of the film thickness; and estimating the thickness of the thin film formed on the substrate in the reaction chamber from the change of the radiation ratio measured in measuring the change of the radiation ratio of the radiant light from the relation between the change of the radiation ratio and the change of the film thickness acquired in acquiring the relation between the change of the radiation ratio and the change of the film thickness.

### BRIEF DESCRIPTION OF THE SEVERAL VIEWS OF THE DRAWING

FIG. 1 is a diagram showing a constitution of a CVD apparatus for use in a film thickness monitoring method according to a first embodiment of the present invention.

FIG. 2 is an enlarged view of the vicinity of a radiation thermometer disposed on a quartz tube as shown by a broken line 2 in FIG. 1.

FIG. 3 is a graph showing a relation between a radiation ratio and an Ru film thickness on a wafer during formation of a ruthenium (Ru) film.

FIG. 4 is a graph showing the relation between the radiation ratio and the thickness of the thin film on the wafer during gas cleaning.

FIG. 5 is a sectional view showing a constitution inside a diffusion furnace for use in a substrate temperature measuring method according to a second embodiment of the present invention.

FIG. 6 is a sectional view of enlarged semiconductor substrate and glass fiber in FIG. 5.

FIG. 7 is a sectional view showing the constitution inside the diffusion furnace for use in the substrate temperature measuring method according to a third embodiment of the present invention.

FIG. 8 is a sectional view showing the constitution inside the diffusion furnace for use in the substrate temperature measuring method according to a fourth embodiment of the present invention.

FIG. 9 is a sectional view showing the constitution inside the diffusion furnace for use in the substrate temperature measuring method according to a fifth embodiment of the present invention.

### DETAILED DESCRIPTION OF THE INVENTION

Embodiments of the present invention will be described hereinafter with reference to the drawings. In the following description, with respect to all the drawings, common portions are denoted with the same reference numerals.

First Embodiment

A film thickness monitoring method in a CVD apparatus according to a first embodiment of the present invention will be described.

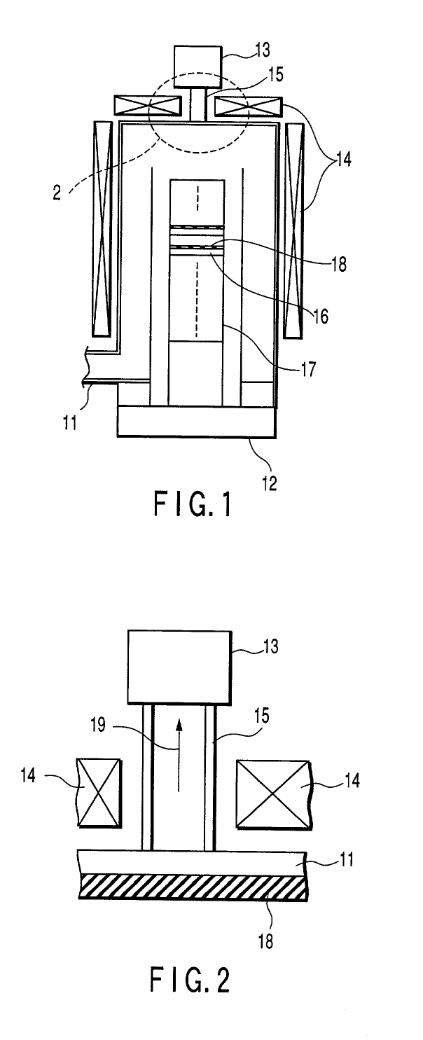

FIG. 1 is a diagram showing a constitution of the CVD apparatus for use in the film thickness monitoring method according to the first embodiment. The CVD apparatus shown in FIG. 1 is a vertical LPCVD apparatus.

As shown in FIG. 1, the vertical LPCVD apparatus includes a reaction chamber having a quartz tube 11, seal cap 12, radiation thermometer (pyrometer) 13, and heater 14. The radiation thermometer 13 is disposed on the quartz tube 11 of the upper part of the reaction chamber via a lead-in tube 15. The heater 14 is disposed on the side surface and upper surface of the quartz tube 11. Furthermore, a boat rod 17 holding a plurality of semiconductor substrates (wafers) 16 is disposed on the seal cap 12 in the vicinity of the middle of the reaction chamber.

FIG. 2 is an enlarged view of the vicinity of the radiation thermometer 13 disposed on the quartz tube 11 as shown by a broken line 2 in FIG. 1. The cylindrical lead-in tube 15 is disposed between the radiation thermometer 13 and the quartz tube 11. The lead-in tube 15 has a function of guiding a radiant light emitted from the quartz tube 11 into the radiation thermometer 13, and intercepting the light coming from peripheries other than the inside of the quartz tube 11.

A film thickness monitoring method of a thin film formed on the wafer 16 using the LPCVD apparatus will next be described.

As described above, to prevent an influence by the light into the radiation thermometer 13 from the heater 14, that is, an influence by a stray light, the cylindrical lead-in tube 15 guides a light 19 from the quartz tube 11 into the radiation thermometer 13. Thereby, the radiation thermometer 13 can measure only the radiation ratio from the quartz tube 11.

A thin film 18 is deposited on the wafer 16 by the LPCVD apparatus. Then, at the same time the formation of the thin film 18 onto the wafer 16 proceeds, the thin film 18 similarly adheres to the inner wall of the quartz tube 11.

The radiation ratio inside the quartz tube 11 during the formation of the thin film is measured with the radiation thermometer 13. As the thin film 18 adheres to the inner wall of the quartz tube 11, the radiation ratio inside the quartz tube 11 viewed from the radiation thermometer 13 changes. This is because the light from the reaction chamber is not easily transmitted because of the thin film 18 adhering to the inner wall of the quartz tube 11.

To solve the problem, the relation between the change of the radiation ratio in each wavelength of the light 19 transmitted through the thin film 18 and quartz tube 11, and the film thickness change of the thin film 18 on the wafer 16 is checked beforehand.

Thereafter, the change of the radiation ratio is read by the radiation thermometer 13 during actual film formation, and the thickness of the thin film 18 on the wafer 16 is estimated from the relation between the radiation ratio and the film thickness checked beforehand. Thereby, during the formation of the thin film, the thickness of the thin film on the wafer can be monitored in situ. Additionally, a wavelength range of the light measured by the radiation thermometer 13 is, for example, of the order of 300 nm to 13000 nm.

The film thickness monitoring method of a ruthenium (Ru) film during formation of the Ru film actually using the CVD apparatus will next be described.

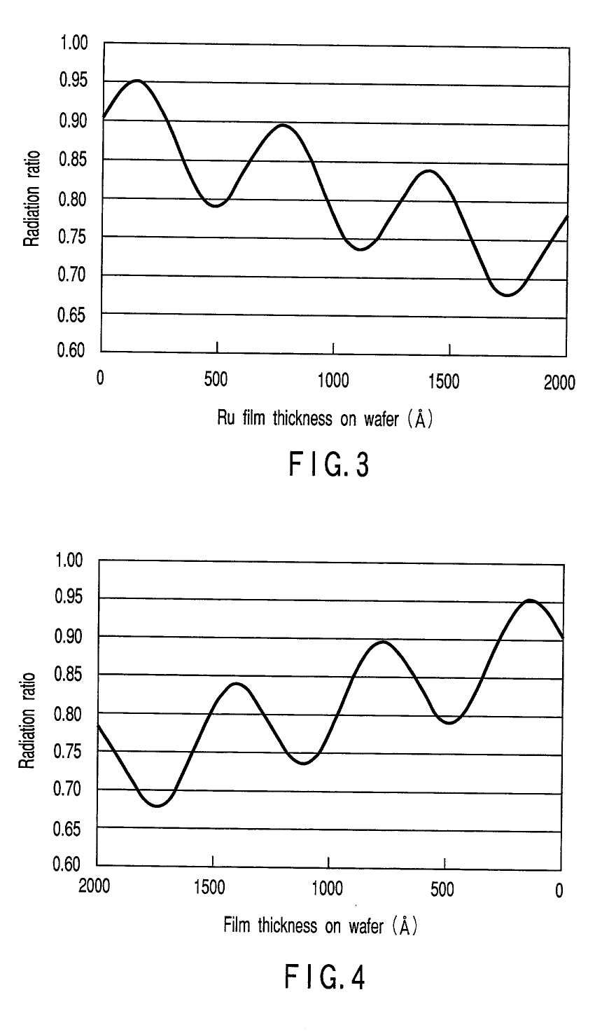

As the formation of the Ru film 18 onto the wafer 16 proceeds, the Ru film 18 having the same thickness as that of the wafer 16 adheres to the inner wall of the reaction chamber. FIG. 3 is a graph showing a relation between the radiation ratio and Ru film thickness on the wafer. The ordinate indicates the radiation ratio, when the whole reaction chamber is considered as one substance, and radiation luminance inside the reaction chamber is seen from the outside of the chamber. The radiation ratio is measured using the radiation thermometer having a single wavelength (5 μm). The abscissa indicates the thickness of the Ru film on the wafer disposed in the reaction chamber.

As shown in FIG. 3, as the thickness of the Ru film on the wafer increases, the radiation ratio draws a sine curve slanting to the right. In this case, the value of the radiation ratio and the number of crests of the sine curve are grasped, and it is therefore possible to monitor the Ru film thickness in the reaction chamber, that is, the thickness of the Ru film on the wafer.

Additionally, in the first embodiment, the use of the radiation thermometer having the single wavelength has been described. However, when the radiation thermometer having multiple wavelengths, measurement precision of the radiation ratio is further raised. Therefore, the monitoring precision of the film thickness can be raised.

An example will next be described in which the film thickness monitoring method is used to judge an end point (etching end time point) of the thin film as a cleaning object during gas cleaning. In the gas cleaning, a reaction gas is supplied into the reaction chamber to perform a CVD process, the thin film is thereby formed on the inner wall of the reaction chamber, and subsequently the etching gas is supplied to etch the thin film.

FIG. 4 is a graph showing the relation between the radiation ratio and the thickness of the thin film formed on the inner wall of the reaction chamber during the gas cleaning.

As shown in FIG. 4, when the thin film of the reaction chamber inner wall is etched, and the film thickness decreases, the radiation ratio inside the quartz tube 11 seen from the radiation thermometer 13 draws the sine curve slanting to the right. In this case, similarly as during the formation of the thin film, the value of the radiation ratio and the number of crests of the sine curve are grasped, and it is thereby possible to monitor the end point during the cleaning. Here, a point at which the radiation ratio becomes constant at 0.9 can be judged to be the end point of the thin film.

That is, the relation between the radiation ratio and the film thickness during etch-off of the thin film is grasped beforehand even during the gas cleaning, and the radiation ratio is measured later during etching, so that it is possible to know the end point of the thin film in situ.

As described above, according to the first embodiment of the present invention, the relation between the radiation ratio and the film thickness is grasped beforehand. When the thin film is formed by the CVD apparatus, the change of the radiation ratio of the light transmitted from the chamber is read with the radiation thermometer, and it is possible to monitor the thickness of the thin film on the wafer in situ based on the relation between the radiation ratio and the film thickness.

Furthermore, even during the gas cleaning, when the thin film formed on the inner wall of the reaction chamber is etched and thinned, the radiation ratio changes. Therefore, the relation between the radiation ratio and the film thickness is grasped beforehand, and the change of the radiation ratio of the light transmitted from the chamber is read with the radiation thermometer during etching, so that it is possible to monitor the end point of the etching in situ based on the relation between the radiation ratio and the film thickness.

The substrate temperature measuring method in the diffusion furnace according to second to fifth embodiments of the present invention will next be described.

Second Embodiment

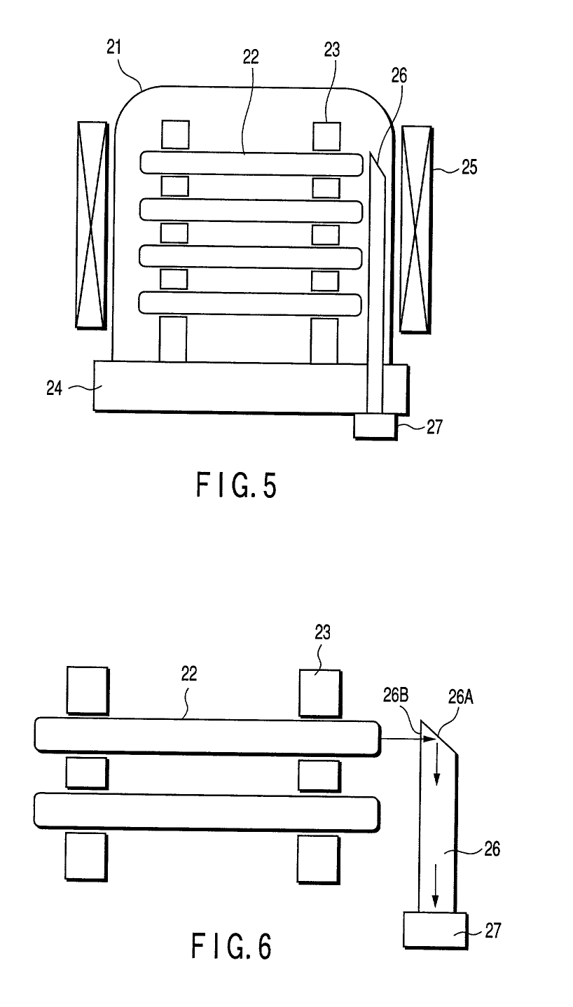

FIG. 5 is a sectional view showing the constitution inside a diffusion furnace for use in a substrate temperature measuring method according to a second embodiment.

As shown in FIG. 5, a boat rod 23 which holds a plurality of semiconductor substrates (wafers) 22 is disposed in a quartz furnace core tube 21. A flange 24 is disposed in a furnace port of the quartz furnace core tube 21, and a heater 25 is disposed around the quartz furnace core tube 21. Furthermore, one of two tip ends of a glass fiber 26 is disposed on the side surface of the semiconductor substrate 22, and the other tip end is connected to a radiation thermometer 27. The glass fiber 26 is formed of quartz.

FIG. 6 is a sectional view showing the semiconductor substrate 22 and glass fiber 26 in FIG. 5 in an enlarged size. As shown in FIG. 6, an inclined surface 26A cut at 45° with respect to a center axis of the glass fiber is formed on one of the tip ends of the glass fiber 26. The inclined surface 26A is finished like a mirror surface, and the light is totally reflected on the surface. Furthermore, in one tip end of the glass fiber 26, a flat and smoothed incidence surface 26B is formed vertical to a plane including a center axis of the glass fiber and a normal of the inclined surface 26A on a side surface opposite to the inclined surface 26A.

In a batch type vertical diffusion furnace, the glass fiber 26 is disposed in such a manner that the inclined surface 26B is disposed opposite to the side surface of the semiconductor substrate 22 as a temperature measurement object. Thereby, the radiant light emitted from the side surface of the semiconductor substrate 22 is taken into the glass fiber 26 via the incidence surface 26B during heat treatment using the diffusion furnace, reflected by the inclined surface 26A and incident upon the radiation thermometer 27. Since the radiant light from the semiconductor substrate 22 is guided into the radiation thermometer 27 in this manner, the temperature of the semiconductor substrate 22 can accurately be measured.

The substrate temperature measuring method is used to measure the substrate temperature, the substrate temperature is controlled, and the thin film is formed on the semiconductor substrate. In this thin film forming process, the substrate temperature measured in the above-described method, pressure in the furnace, and gas flow rate are used to calculate the thickness of the formed thin film. When a calculated value reaches a target film thickness, the thin film formation is ended.

As described above, in the second embodiment, the inclined surface 26A having the mirror surface is formed in the tip end of the glass fiber 26, and the light emitted from the side surface of the semiconductor substrate 22 is reflected by the inclined surface 26A of the glass fiber 26, and guided into the radiation thermometer 27. Thereby, the substrate temperature can accurately be measured. Furthermore, in a thin film forming process, the substrate temperature measuring method is used to measure the substrate temperature, and the substrate temperature is accurately controlled. Therefore, the thickness of the formed thin film can accurately be calculated, and a deviation amount from a target film thickness can be reduced.

Third Embodiment

FIG. 7 is a sectional view showing the constitution inside the diffusion furnace for use in the substrate temperature measuring method according to a third embodiment.

In addition to the constitution of the second embodiment shown in FIG. 6, the diffusion furnace for use in the substrate temperature measuring method of the third embodiment has a constitution in which an opaque quartz substrate 31 is disposed with a space on the inclined surface 26A formed on one tip end of the glass fiber 26. As shown in FIG. 7, the opaque quartz substrate 31 is allowed to contact one end of the inclined surface 26A, and disposed apart from the other end. The space is preferably present between the inclined surface 26A and the opaque quartz substrate 31, and the space is set to a minimum processable distance, for example, of about 0.2 mm. The other constitution is similar to the constitution in the second embodiment, and denoted with the same reference numerals, and the description thereof is omitted.

In the second embodiment, only the inclined surface 26A having a mirror-surface state is formed on the tip end of the glass fiber 26. Therefore, a part (stray light) of the radiant light from a high temperature portion of the upper part of the diffusion furnace is taken into the glass fiber 26, and the measurement precision of the substrate temperature is sometimes insufficient.

To solve the problem, in the third embodiment, the opaque quartz substrate 31 is disposed on the inclined surface 26A on the tip end of the glass fiber 26. Thereby, the radiant light from the high temperature portion of the upper part of the diffusion furnace is scattered by the opaque quartz substrate 31, and the amount of the light taken into the glass fiber 26 can remarkably be decreased. As a result, the measurement precision of the substrate temperature can further be enhanced as compared with the second embodiment, and the deviation amount from the target thickness of the formed thin film can further be reduced as compared with the second embodiment.

Additionally, in the third embodiment, when the opaque quartz substrate 31 contacts the inclined surface 26A, the total reflection of the radiant light does not occur in the inclined surface 26A, and the measurement precision of the substrate temperature is not improved. Therefore, it is necessary to make a gap between the inclined surface 26A of the glass fiber 26 and the opaque quartz substrate 31 in such a manner that the inclined surface does not contact the substrate.

Fourth Embodiment

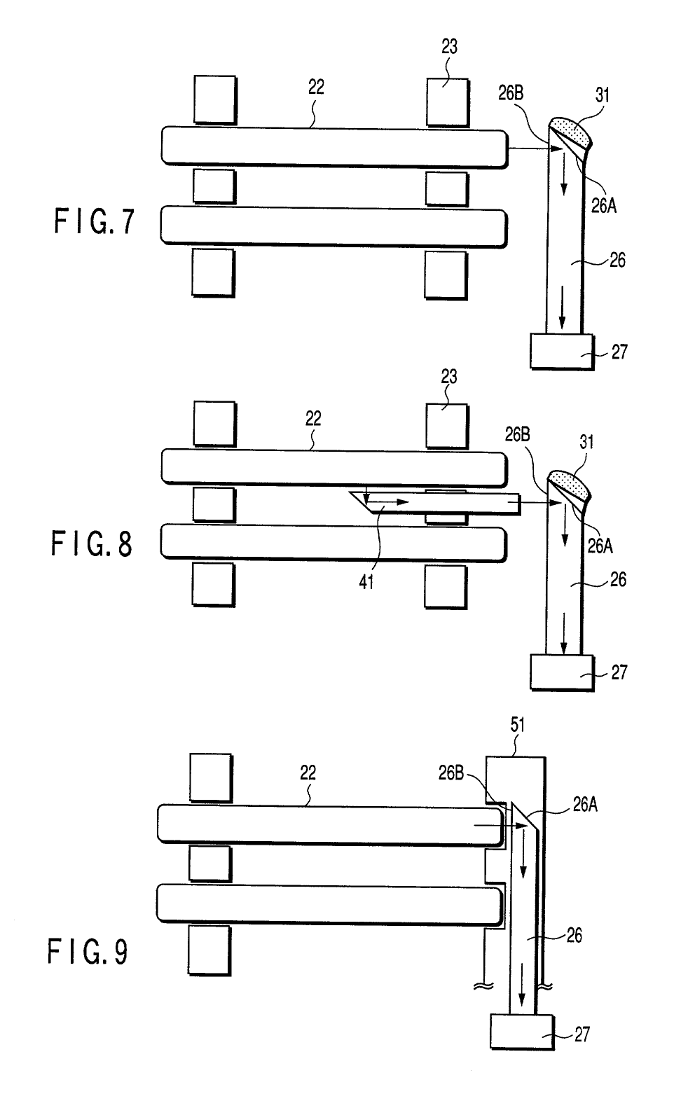

FIG. 8 is a sectional view showing the constitution inside the diffusion furnace for use in the substrate temperature measuring method according to a fourth embodiment.

In addition to the constitution of the third embodiment shown in FIG. 7, the diffusion furnace for use in the substrate temperature measuring method of the fourth embodiment has a constitution in which the boat rod 23 holds a quartz prism 41, and the quartz prism 41 is disposed under the lower main surface (lower surface) of the semiconductor substrate 22.

The quartz prism 41 has one of two tip ends cut at an angle of 45 degrees, and the other tip end is cut at a right angle. Moreover, in one tip end, the surface which is not cut at 45 degrees is disposed opposite to the surface of the semiconductor substrate 22. The surface cut at the right angle in the other tip end is disposed opposite to the incidence surface 26B of the glass fiber 26.

In the fourth embodiment, since the surface temperature of the main surface of the semiconductor substrate 22 having stabilized shape and surface state can be measured, the measurement precision of the substrate surface can be enhanced. Thereby, the deviation amount from the target thickness of the formed thin film can be reduced. Additionally, an example of measurement of the temperature of the lower main surface (lower surface) of the substrate is shown in FIG. 8, but the temperature of the upper main surface (upper surface) of the substrate can also be measured. To measure the temperature of the upper surface of the substrate, the 45-degrees inclined surface of the quartz prism 41 may be turned upwards.

Fifth Embodiment

FIG. 9 is a sectional view showing the constitution inside the diffusion furnace for use in the substrate temperature measuring method according to a fifth embodiment.

The diffusion furnace for use in the substrate temperature measuring method of the fifth embodiment is constituted by forming a boat rod 51 to be hollow and disposing the glass fiber 26 in the boat rod 51 in the constitution of the first embodiment shown in FIG. 6.

Similarly as the first embodiment, the inclined surface 26A cut at 45 degrees, and the incidence surface 26B formed on a side opposite to the inclined surface 26A are formed in one tip end of the glass fiber 26. Moreover, the incidence surface 26B of the glass fiber 26 is disposed opposite to the side surface of the semiconductor substrate 22 as the temperature measurement object. Additionally, the boat rod 51 is formed of silicon carbide (SiC), and is hollow. Therefore, an SiC layer does not exist between the semiconductor substrate 22 and the incidence surface 26B of the glass fiber 26.

In the fifth embodiment, the glass fiber 26 disposed in the boat rod 51 is used to take the radiant light from the side surface of the semiconductor substrate 22 into the glass fiber 26 via the incidence surface 26B. The light is reflected by the inclined surface 26A, and is incident upon the radiation thermometer 27. As a result, an accurate substrate temperature can be obtained.

Therefore, the substrate temperature measuring method is used to measure the substrate temperature, and the substrate temperature is accurately controlled in the thin film forming process, so that the thickness of the formed thin film can accurately be calculated, and the deviation amount from the target film thickness can be reduced.

The respective vertical diffusion furnaces of the second to fifth embodiments, and first and second comparative examples were used to perform hydrogen combustion oxidation at a temperature of 750° C., and an oxide film was formed on the silicon semiconductor substrate. Results are shown in the following. In the first comparative example, to know the substrate temperature, an in-furnace temperature was measured with a thermocouple disposed in the furnace. In the second comparative example, the inclined surface was brought into contact with the opaque quartz substrate in the third embodiment, and the space was set, for example, to 0.005 mm.

In the forming process of the oxide film, the thickness of the oxide film on the substrate was measured from the monitored in-furnace pressure, substrate temperature or in-surface temperature, and gas flow rate. When the calculated value reached 8 nm, the oxidation process was ended.

Thereafter, the thickness of the oxide film formed on each substrate was measured by erypsometry. As a result, a magnitude relation of the deviation amount from the target film thickness of 8 nm was the fourth embodiment<third embodiment<second, fifth embodiments<second comparative example<first comparative example. In any embodiment, the film thickness deviation amount from the target film thickness of 8 nm can be suppressed to ±2% or less. It can be confirmed from the above that the deviation amount from the target thickness of the oxide film formed on the substrate can be reduced using the substrate temperature measuring method of the second to fifth embodiments.

Moreover, in the second to fifth embodiments, an example in which quartz is used in the glass fiber has been described. However, it has been confirmed that even with the use of sapphire other than quartz, the result similar to that of the embodiment can be obtained.

Furthermore, the respective embodiments can be implemented alone, an appropriate combination of the embodiments can also be implemented. Additionally, the respective embodiments include various stages of the invention. It is also possible to extract various stages of the invention by the appropriate combination of a plurality of constituting elements disclosed in each embodiment.

As described above, according to the embodiments of the present invention, there can be provided the film thickness monitoring method in which the thickness of the thin film on the substrate in the reaction chamber of the CVD apparatus can be monitored in situ. Moreover, there can be provided the substrate temperature measuring method in which the substrate temperature can be measured in the batch type diffusion furnace.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general invention concept as defined by the appended claims and their equivalents.

What is claimed is:

1. A film thickness monitoring method comprising:
measuring a radiant light from a reaction chamber outside said reaction chamber, and acquiring a relation between a change of a radiation ratio of said radiant light, and a change of a thickness of a thin film formed on a substrate, when a chemical vapor deposition (CVD) apparatus having the reaction chamber is used to form the thin film on the substrate in said reaction chamber;
measuring the change of said radiation ratio of said radiant light, when said CVD apparatus is used to form the thin film on the substrate after acquiring the relation between the change of said radiation ratio and the change of said film thickness; and
estimating the thickness of said thin film formed on the substrate in said reaction chamber from the change of said radiation ratio measured in measuring the change of said radiation ratio of said radiant light from the relation between the change of said radiation ratio and the change of said film thickness acquired in acquiring the relation between the change of said radiation ratio and the change of said film thickness.

2. The film thickness monitoring method according to claim 1, wherein said radiant light is a light which is emitted from said reaction chamber, and transmitted through the thin film adhering to the inner wall of said reaction chamber and a wall material of said reaction chamber.

3. The film thickness monitoring method according to claim 1, wherein the radiation ratio of said radiant light is measured by a radiation thermometer disposed outside said reaction chamber.

4. The film thickness monitoring method according to claim 3, further comprising: disposing a lead-in tube between said reaction chamber and said radiation thermometer; removing the light from peripheries other than the inside of said reaction chamber by said lead-in tube; and guiding only said radiant light into said radiation thermometer by the lead-in tube.

5. A film thickness monitoring method comprising:
measuring a radiant light from a reaction chamber outside said reaction chamber, and acquiring a relation between a change of a radiation ratio of said radiant light and a change of a thickness of a thin film present on an inner wall of said reaction chamber, when a reaction gas is supplied into the reaction chamber to form the thin film on the inner wall of said reaction chamber, and subsequently an etching gas is supplied into said reaction chamber to etch said thin film;
measuring a change of said radiation ratio of said radiant light, when the reaction gas is supplied into said reaction chamber to form the thin film on the substrate in said reaction chamber after acquiring the relation between the change of said radiation ratio and the change of said film thickness, the thin film is formed on the inner wall of said reaction chamber, and subsequently the etching gas is supplied into said reaction chamber to etch said thin film; and
estimating the thickness of said thin film remaining on the substrate in said reaction chamber from the change of said radiation ratio measured in measuring the change of said radiation ratio of said radiant light from the relation between the change of said radiation ratio and the change of said film thickness acquired in acquiring the relation between the change of said radiation ratio and the change of said film thickness.

6. The film thickness monitoring method according to claim 5, wherein said estimating of the thickness of said thin film remaining on said substrate comprises: estimating a timing at which said thin film is etched off.

7. The film thickness monitoring method according to claim 5, wherein said radiant light is a light which is emitted from said reaction chamber, and transmitted through the thin film adhering to the inner wall of said reaction chamber and a wall material of said reaction chamber.

8. The film thickness monitoring method according to claim 5, wherein the radiation ratio of said radiant light is measured by a radiation thermometer disposed outside said reaction chamber.

9. The film thickness monitoring method according to claim 8, further comprising: disposing a lead-in tube between said reaction chamber and said radiation thermometer; removing the light from peripheries other than the inside of said reaction chamber by said lead-in tube; and guiding only said radiant light into said radiation thermometer by the lead-in tube.

10. A substrate temperature measuring method comprising:
disposing a cylindrical bar shaped glass fiber having one tip end and the other tip end in such a manner that a flat surface formed on said one tip end is disposed opposite to a side surface vertical to a main surface of a substrate as a temperature measurement object, said glass fiber having said flat surface parallel to a center axis of said glass fiber, and an inclined surface slantly cut with respect to the center axis of said glass fiber on said one tip end; and
taking a light emitted from the side surface of said substrate into the glass fiber via said flat surface, reflecting the light by said inclined surface on said one tip end and guiding the light to said other tip end.

11. The substrate temperature measuring method according to claim 10, wherein the substrate as said temperature measurement object is one of a plurality of substrates disposed in a batch type diffusion furnace.

12. The substrate temperature measuring method according to claim 10, wherein said inclined surface of said glass fiber is cut at 45 degrees with respect to the center axis of the glass fiber, and said inclined surface has a mirror surface state.

13. The substrate temperature measuring method according to claim 10, wherein an opaque substrate is formed with a space from the surface of said inclined surface on said inclined surface of said glass fiber.

14. The substrate temperature measuring method according to claim 10, further comprising:
using a prism having one tip end and the other tip end, and disposing the prism in such a manner that the side surface of said one tip end is disposed opposite to the main surface of the substrate as said temperature measurement object, and said other tip end is disposed opposite to said flat surface of said glass fiber,
said prism having an inclined surface cut at 45 degrees with respect to the center axis of said prism on the side opposite to said side surface of said one tip end.

15. The substrate temperature measuring method according to claim 10, wherein the substrate as said temperature measurement object is held by a holding member having a hollow inner part, and said glass fiber is disposed inside said holding member.
